(19) United States
(12) Patent Application Publication
(10) Pub. No.: US 2001/0043073 A1
(43) Pub. Date: Nov. 22, 2001

(54) PROBER INTERFACE PLATE

(76) Inventor: THOMAS T. MONTOYA, AUSTIN, TX (US)

Correspondence Address: DYKEMA GOSSETT PLLC, 39577 WOODWARD AVENUE, BLOOMFIELD HILLS, MI, 48304-2820, US

(21) Appl. No.: 09/264,748

(22) Filed: Mar. 9, 1999

(51) Int. Cl. G01R 31/02

(52) U.S. Cl. 324/754

(57) ABSTRACT

A prober interface plate is formed as a single body of ceramic material. The plate has highly planar surfaces obtained by machining and polishing the ceramic plate.

### TECHNICAL FIELD

The present invention relates generally to apparatus for testing semiconductor wafer devices, and more specifically, to apparatus used to hold a probe card of the type used for testing circuits on a semiconductor wafer.

### BACKGROUND OF THE INVENTION

In the manufacture of semiconductor devices, a number of discrete circuits are formed on the wafer surface using photolithographic techniques. In essence, these circuits are highly miniaturized electrical devices through which electrical current moves in a desired path. The techniques used to form these circuits are extremely sensitive and occasionally result in an inoperative circuit. That is, one or more discrete circuits on a wafer may fail to operate properly. Accordingly, it is important to identify these failed circuits before the wafer is die cut so that they are not incorporated into microelectronic devices.

In order to test the various discrete circuits on the semiconductor wafer, probing devices have been developed in which an array of probe elements extend from a probe card in a pattern which matches contact points or pads on the wafer surface. The layout of circuits may of course vary between semiconductor wafers depending on the use thereof, e.g. a memory wafer may differ in its circuit layout from a microprocessor wafer. This requires that the arrangement of the probe elements on the probe card correspond to or mate with each type of wafer. This is accomplished by providing a carrier in which the probe cards can be changed when necessary.

A typical test apparatus includes a prober, a test head and a tester. A semiconductor wafer is placed inside the prober. A probe card is placed inside a cavity of a prober interface plate that is pre-mounted superjacent to a head plate of the prober. In this manner, the probe card can simply be lifted out of the cavity whenever a probe card changeover is required. A tester interface plate is pre-mounted to the test head. The two interface plates have mating engagement locking features. An improved apparatus for forming a test head for semiconductor wafer probing is disclosed in U.S. Pat. No. 5,656,943, the entire disclosure of which is incorporated by reference. Therein a probe card fits within a specially designed cavity of a prober interface plate that is pre-mounted superjacent to a head plate of a prober. The bottom surface of the cavity provides solid and uniform support for the probe card. The probe card can be lifted out of the cavity whenever a probe card changeover is required. The tester interface plate is pre-mounted to the test head. The tester interface plate has interlocking alignment pins which is self-aligned into mating chamfered alignment holes in the prober interface plate. Additionally, the two interface plates have mating interlocking features for increased stability. The test stack allows the probe card to contact, typically through cantilever pins to contact the active surface of the semiconductor wafer.

There is, however, a need for increased control over the tolerances of the prober interface plate. Most prober interface plates are composed of stainless steel. While these metal prober interface plates are functional, it would be desirable to provide prober interface plates which can be reproducibly manufactured with significantly tighter tolerances to insure that the planer alignment of the probe elements are such that substantially all of the probe elements contact their respective contact points on the wafer. As will be appreciated by those skilled in the art, even small deviations from the ideal plane caused by nonplanar surfaces in the prober interface plate can cause false negatives. The present invention addresses these needs.

### SUMMARY OF THE INVENTION

The present invention provides a prober interface plate having a carrier rim and a probe card carrier surface. In the center of the probe card carrier surface an aperture is formed which has the same shape as the shape of a probe card. The probe interface plate is formed of a ceramic material such as alumina or zirconia and may be covered with silicon carbide as a single body. Forming the probe an interface plate as a single body of ceramic material allows tighter tolerances to be achieved in the planar surfaces.

### BRIEF DESCRIPTION OF THE DRAWINGS

FIG. 1 illustrates, in perspective view, a prober interface plate made in accordance with the present invention.

FIG. 2 illustrates a schematic of a test stack composed of a prober, its head plate, an interface and a test head.

### DETAILED DESCRIPTION OF THE PREFERRED EMBODIMENTS

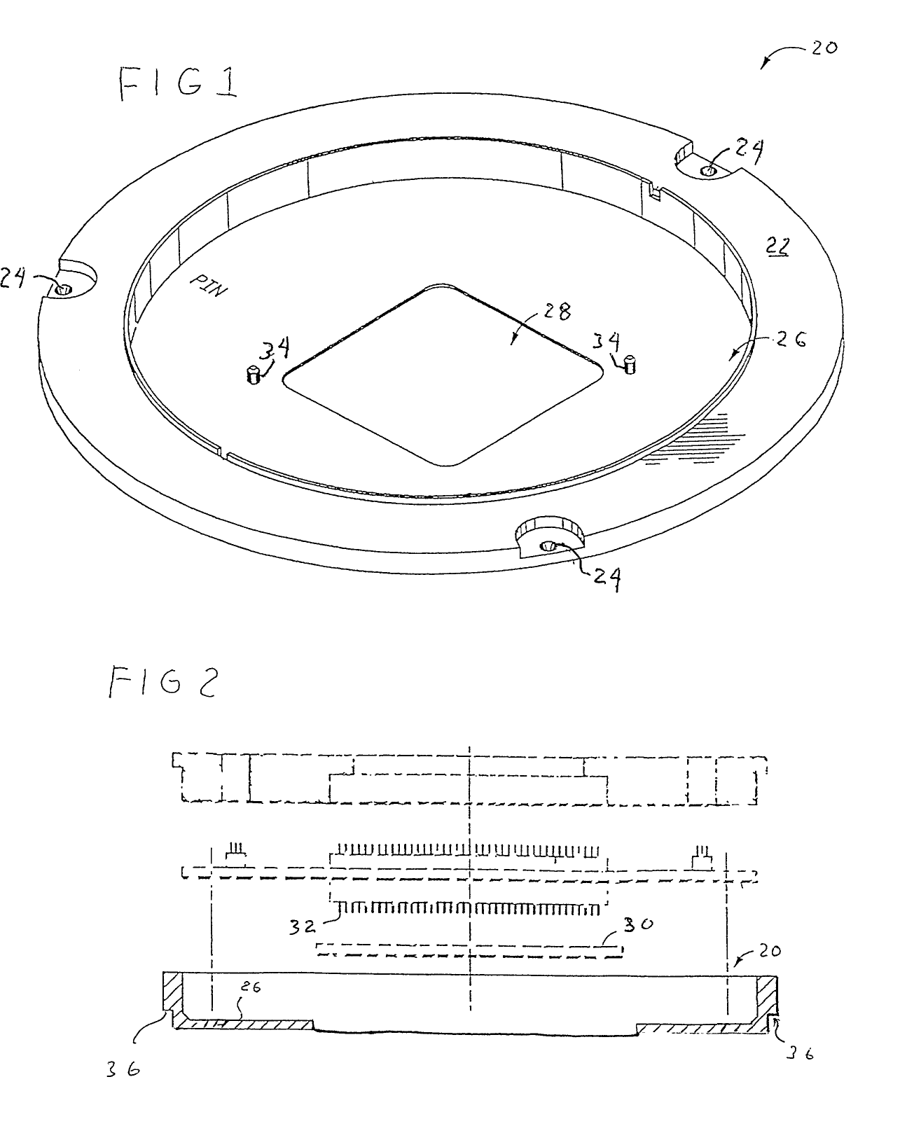

Referring now to FIGS. 1 and 2, a generic ceramic prober interface plate 20 is shown made in accordance with the present invention. Prober interface plate 20 has a carrier rim 22 for handling. In the carrier rim 22 are holes 24 which are located to match to holes on the head plate of a prober either manually or by auto probe card changers so that the prober interface plate 20 can be pre-mounted to a head plate. Although not limited to any particular dimensions, physical dimensions of a prober interface plate is preferably approximately 20.5″×25.5″×1.56″ (52 cm ×65 cm ×4 cm). In the center of the prober interface plate 20 is probe card carriers or support surface 26 having an aperture 28 which is of the same shape as the shape of a probe card 30. The thickness of the bottom plate portion 28 which permits probe needles 26 to extend therethrough is approximately 0.762 mm/0.03″. The central aperture 28 is present so that probe needles 32 can contact the semiconductor wafer that would be supported inside the prober for testing purposes.

As will be appreciated by those skilled in the art, prober interface plate 20 will have various alignment pins and the like, such as pins 34 for assembly of the test assembly stack, which will vary depending on the specific design. Thus, only a generic test plate is shown.

Prober interface plate 20 can be pre-mounted to the head plate of the prober. Once mounted, the prober interface plate can be lifted out of the cavity and changed manually or by automatic probe card changers.

The prober interface plate would be mounted superjacent to a head plate of a prober (not shown) and the tester interface plate would be mounted subjacent to a test head (not shown).

In a method of testing a semiconductor wafer using the apparatus of the present invention, the semiconductor wafer to be tested is placed inside the prober on a support chuck or the like. The head plate of the prober already has the prober interface plate premounted thereon. An appropriate probe card for the given semiconductor wafer is placed inside the prober interface plate. The test head has the tester interface plate pre-mounted thereon. The operator then re-aligns the tester interface plate with the prober interface plate. The appropriate electrical test can then be run to determine the functionality of the individual devices on the semiconductor wafer.

As stated previously, probe interface plate 20 of the present invention is formed as a single ceramic body. One suitable method of manufacture will hereinafter be described. It should be understood that the method described below is only one of several methods that may be utilized by one skilled in the art to manufacture the present invention. The method of constructing probe interface plate 20 of the present invention comprises a series of steps. The first step involves using as a starting material aluminum oxide (or zirconia) powder that preferably has an average particle diameter of 8-12 microns with the range of particle diameters being preferably 2-25 microns. The aluminum oxide powder is preferably highly purified 99.5% or more. Sintering aids and binding aids may be added to the aluminum oxide powder prior to baking as is well known in the art. The second step involves forming the above-mentioned starting powder into ceramic green billets utilizing an isostatic press that subjects the starting powder to preferably at least a 7000 PSI pressure. It should be understood that a separate green billet will be formed to manufacture each probe interface plate 20 of the present invention. The fourth step involves machining each green billet to include the features of probe interface plate 20 shown in FIG. 1 of the drawings. The machining step includes machining the various cavities and surfaces according to the teachings of the present invention. The fifth step involves baking the green billets at preferably approximately 1650° C. The sixth step involves diamond grinding of the various cavities and features of probe interface plate 20. Optionally, a thin nonporous glass coating for example silicon carbide over probe interface plate 20 may be applied that has a melting point lower than that of the aluminum oxide. A doping agent may be added to the glass coating material to increase the resistance of the glass coating. For example, the doping agent may comprise one or more of the following chemical compounds: zirconia, silicon carbide, titungsten, silicon nitride, titanium diboride, boron carbide, aluminum titanate, tungsten carbide, and aluminum nitride. The glass coating preferably has a thickness of 100 Å or less. This coating is not believed necessary when zirconia is used as the ceramic for the plate body.

An important feature of the present invention is the planarity or “flatness” of surface 26 and surface 36 (which rest on the prober stage head). These surfaces should be as flat as possible. Preferably these surfaces have a planarity of 300 Å±100 Å. More stringent planarities may be achievable with the present invention.

Although the invention has been described and illustrated with reference to specific embodiments thereof, it is not intended that the invention be limited to these illustrative embodiments. Those skilled in the art will recognize that modifications and variations can be made without departing from the spirit of the invention.

I claim:

1. A prober interface plate for holding a probe plate, said prober interface plate being formed of a ceramic material.

2. The prober interface plate recited in claim 1, wherein said prober interface plate is a single unitary body.

3. The prober interface plate recited in claim 1, wherein said ceramic material is selected from the group consisting of aluminum, zirconia, and combinations thereof.

4. The prober interface plate recited in claim 1, said prober interface plate having a carrier rim and a support surface for holding a probe card.

5. The prober interface plate recited in claim 4, further comprising an aperture in said support surface.

6. The prober interface plate recited in claim 1, wherein the planarity of the support surface is about 300 Å±100 Å.
